(19) United States
(12) Patent Application Publication
(10) Pub. No.: US 2006/0034131 A1
(43) Pub. Date: Feb. 16, 2006

(54) Receiver and storage control method

(75) Inventors: Atsuhiro Ono, Kitaura (JP); Kazuto Shimagami, Mito (JP)

Correspondence Address: MCDERMOTT WILL & EMERY LLP, 600 13TH STREET, N.W., WASHINGTON, DC, 20005-3096, US

(73) Assignee: HITACHI, LTD.

(21) Appl. No.: 11/140,286

(22) Filed: May 31, 2005

(30) Foreign Application Priority Data
Aug. 11, 2004 (JP) 2004-234074

(51) Int. Cl. G11C 7/10

(52) U.S. Cl. 365/189.05

(57) ABSTRACT

In a data recording/reproducing unit, an identification of the storage unit is validated, to prevent circumvention of copy protection by unauthorized replacement of the storage unit. For example, when the power of a television receiver 100 is turned on for the first time, the controller 150 reads out a HDD serial number stored in a HDD 140, and then writes the number to a flash memory 160. While the receiver 100 is ON, the controller 150 acquires the HDD serial number stored in the HDD 140 periodically or every time there is an attempt to access the HDD 140. Then, the controller 150 compares the acquired HDD serial number to the HDD serial number in the flash memory 160. If the result of the judgment is negative, the controller 150 disallows the use of the HDD 140.

### REFERENCE TO PRIORITY APPLICATION

This application claims the benefit of Japanese Application No. 2004-234074 filed in Japan on Aug. 11, 2004, the disclosure of which also is entirely incorporated herein by reference.

### TECHNICAL FIELD

The techniques disclosed herein relate to a technique for controlling how to store data in a storage device.

### BACKGROUND

Conventional technologies for preventing data from being illegally used, for example, are disclosed in patent documents EP1037460A2 and U.S. 2003120942A1.

The patent document EP1037460A2 discloses the technique as described below. To be more specific, when transmitting data from a first recording medium to a second recording medium, a first device encrypts data using a device-specific identifier thereof as a key, and then transmits the encrypted data to a second device. The encrypted data, which has been transmitted to the second device, is written to the second recording medium. When the second device reproduces the encrypted data transmitted from the first device, the second device checks whether or not the second device is connected to the first device. In a state in which the second device is connected to the first device, the encrypted data is read out into the first device, and the first device decrypts the encrypted data using the above-mentioned identifier as the key, and then reproduces and outputs the data.

The published patent application document U.S. 2003120942A1 discloses the technique as described below. To be more specific, a hard disk drive encrypts data, which has been transmitted from an interface, before writing the encrypted data to recording means, and decrypts data, which has been written to the recording means, before transmitting the decrypted data to the interface.

### SUMMARY

According to the above-mentioned technologies, it is possible to prevent data from being output as usable data from devices other than an authorized device (for example, a device having a decryption key). However, the technologies described above cannot prevent encrypted data from being written to an unauthorized storage device (for example, another storage device that is different from a previously mounted storage device), and cannot prevent the encrypted data, which has been written to the unauthorized storage device, from being output as usable data.

Therefore, an objective of the present technique is to prevent a storage device from being illegally used, e.g. to circumvent copy control technologies or procedures.

Hence, an identification of the storage unit of a data recording/reproducing unit is validated, to prevent circumvention of copy protection by unauthorized replacement of the storage unit. If a storage unit identification does not match a valid identification, e.g. because units have been illegally swapped to avoid copy restrictions, then access to the invalid storage unit is disabled.

For example, a receiver includes an input unit for receiving a signal containing broadcast data, such as digital television broadcast data, and a storage unit for storing the received data. The storage unit has identification data which specifies the storage unit, e.g. in a storage area separate from that which stores the broadcast data. The receiver also includes a controller for controlling access to the storage unit and a memory storing valid identification data. The controller acquires the storage unit identification data from the storage unit and compares it with the valid identification data stored in the memory. The controller allows access to the storage unit only if the acquired storage unit identification data coincides with the valid identification data.

In a specific example, the receiver is a television receiver. The receiver includes a television tuner and a video display. The receiver may also include circuitry for encrypting the received data for storage and for decrypting stored data retrieved from the storage unit.

As disclosed, the controller denies access if the identification data of the storage unit is not valid. The controller may check the identification data periodically, or the controller may check the identification data every time there is an attempt to access the storage unit. Periodic checking, for example, might entail checking at regular intervals or checking each time that the receiver is turned ON after initial programming of the valid identification data. Of course, the controller may check for coincidence of the identification data at other times.

In the examples, the storage unit comprises a hard disk drive (HDD), and the HDD serial number is used as the identification data. A valid serial number may be programmed into the receiver memory by the manufacturer. A technique is also disclosed for capturing and storing the serial number from an HDD initially installed in the receiver, the first time that the receiver is powered-up.

The present teachings also relate to a storage control method, for controlling the use of a storage device having an identification data. The method involves acquiring the identification data from the storage device when the power is first turned on and storing the acquired data. During a subsequent operation, identification data is acquired from a storage device (e.g. which may or may not be the same valid device). The method allows the access to the storage device only if the stored identification data and the identification acquired during the later operation match each other.

The present teachings also encompass a program product comprising instructions for causing a programmable device to perform the steps of the method outlined above.

Moreover, various kinds of devices, such as a hard disk drive, and a DVD (Digital Versatile Disk) drive, can be adopted as the storage device.

It is to be noted that the storage control system is not necessarily required to be equipped with a storage device itself. Furthermore, the storage control system can be applied to various kinds of computer systems including, for example, television apparatuses, personal computers, and recording/reproducing devices (for example, hard disk recorders).

Additional objects, advantages and novel features will be set forth in part in the description which follows, and in part will become apparent to those skilled in the art upon examination of the following and the accompanying drawings or may be learned by production or operation of the examples. The objects and advantages of the present teachings may be realized and attained by practice or use of the methodologies, instrumentalities and combinations particularly pointed out in the appended claims.

### BRIEF DESCRIPTION OF THE DRAWINGS

The drawing figures depict one or more implementations in accord with the present teachings, by way of example only, not by way of limitation. In the figures, like reference numerals refer to the same or similar elements.

FIG. 1 is a block diagram illustrating a configuration of the television receiver to which the storage control technique is applied.

FIG. 2 is a flowchart illustrating operation of storing a HDD serial number in the flash memory 160.

FIG. 3 is a flowchart illustrating operation performed when the power of the television apparatus 100 is turned on for the second time or later.

FIG. 4 is a flowchart illustrating operation performed while the power of the television apparatus 100 stays in an ON state.

### DETAILED DESCRIPTION

In the following detailed description, numerous specific details are set forth by way of examples in order to provide a thorough understanding of the relevant teachings. However, it should be apparent to those skilled in the art that the present teachings may be practiced without such details. In other instances, well known methods, procedures, components, and circuitry have been described at a relatively high-level, without detail, in order to avoid unnecessarily obscuring aspects of the present teachings.

A television apparatus to which a storage control system according to one embodiment of the present technique is applied will be described with reference to drawings as below. In this embodiment, as described below, a hard disk drive (hereinafter referred to as “HDD”) is built into the television receiver apparatus. Every time the television apparatus makes an access to the HDD, the television apparatus compares a hard disk ID stored in the HDD with a hard disk ID stored in a nonvolatile memory included in the television apparatus. Then, on the basis of the result of the comparison, the television apparatus controls whether to allow writing of digital content to the HDD, or whether to allow reading of digital content from the HDD.

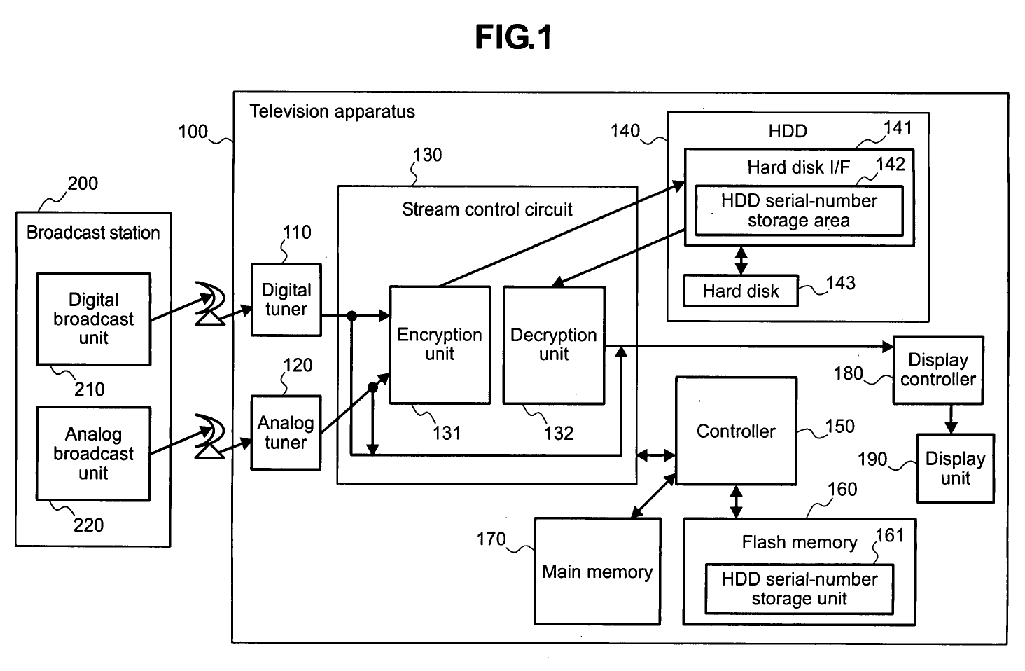

FIG. 1 is a block diagram illustrating a configuration of the television apparatus to which the storage control system according to one embodiment of the present technique is applied.

A broadcast station 200 comprises, for example, a digital broadcast unit 210 for delivering digital broadcast services, and an analog broadcast unit 220 for delivering analog broadcast services. A digital broadcast signal (for example, transport stream data in the MPEG2 format), which is output from the digital broadcast unit 210, is received by a digital tuner unit 110 included in the television apparatus 1100. An analog broadcast signal, which is output from the analog broadcast unit 220, is received by an analog tuner 120.

The television apparatus 100 comprises the digital tuner 110, the analog tuner 120, a stream control circuit 130, a HDD 140, a display controller 180, a display unit 190, a controller 150, a flash memory 160, and a main memory 170.

The digital tuner 110 selects a signal from the received digital broadcast signal (that is to say, a signal corresponding to a selected channel and possibly a program selected from a stream carried on that channel), and then outputs the selected signal. The analog tuner 120 selects a signal detected from the received analog broadcast signal, and then outputs the selected signal.

Under the control of the controller 150, the stream control circuit 130 controls digital content (for example, video data) represented by the signal which is output from the digital tuner 110 or the analog tuner 120 (hereinafter they are generically designated as “tuner”) so that the digital content is displayed in the display unit 190 through the display controller 180 or is stored in the HDD 140. The stream control circuit 130 comprises: an encryption unit 131 for encrypting data represented by the signal output from the tuner; and a decryption unit 132 for decrypting encrypted digital content. The stream control circuit 130 uses the encryption unit 131 to encrypt the digital content, which is output from the tuner, and then transmits the encrypted digital content to the HDD 140 for storage. In addition, the stream control circuit 130 uses the decryption unit 132 to decrypt the digital content (the encrypted digital content) read out from the HDD 140, and then outputs the decrypted digital content to the display controller 180.

The HDD 140 comprises: a hard disk 143 capable of storing the digital content; and a hard disk interface device (hereinafter referred to as “hard disk I/F”) 141 for controlling writing/reading of the digital content to/from the hard disk 143. The hard disk I/F has a HDD serial-number storage area 142 in which a serial number specific to the HDD 140 (hereinafter referred to as “HDD serial number”) is stored. Incidentally, in this embodiment, although the serial number as described above is adopted as information to be stored in the HDD serial-number storage area 142, the information stored in the storage area 142 is not limited to the serial number specific to the HDD 140. Any information may also be used so long as the information can uniquely identify the HDD 140. In addition, the HDD serial-number storage area 142 can be allocated on, for example, a nonvolatile memory.

The display controller 180 displays, on the display unit (display screen) 190, a signal (in particular, video data) received from the stream control circuit 130. The display unit 190 is, for example, a CRT, a liquid crystal, a projection TV screen or a plasma display screen.

What is stored in the flash memory 160 is at least one kind of information relating to the control of the television apparatus 100. For example, the flash memory 160 is provided with a HDD serial-number storage unit 161 in which a HDD serial number is stored. The flash memory 160 also stores executable code for the program(s) run by the controller 150 to implement desired control and operations of the apparatus 100. It is to be noted that instead of the flash memory 160, another kind of nonvolatile memory may also be used.

The main memory 170 is a memory used as a work area of the controller 150. A volatile memory or a nonvolatile memory can be adopted as the main memory 170.

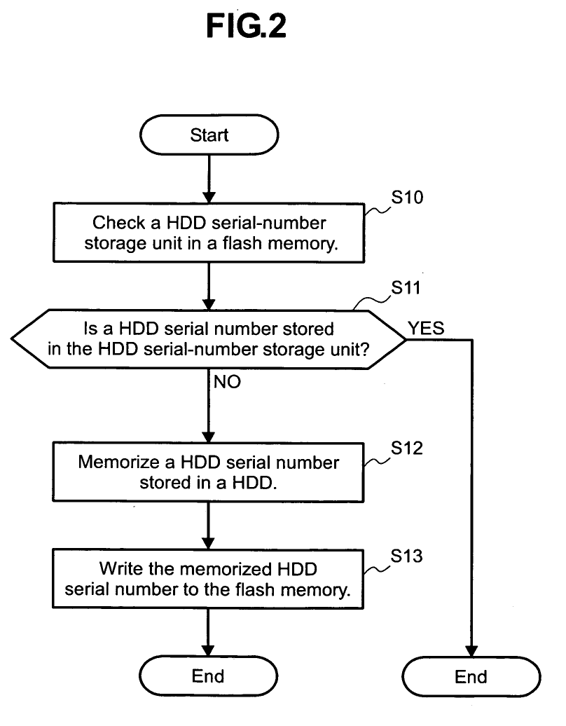

The controller (for example, CPU) 150 controls the total operation of the television apparatus 100, in accord with programming stored in flash memory 160. Next, the operation performed by the controller 150 will be described with reference to FIG. 2 and subsequent figures.

FIG. 2 is a flowchart illustrating the operation performed by the controller 150 when the power of the television apparatus 100 is turned on for the first time.

As shown in FIG. 2, when the power of the television apparatus 100 is turned on for the first time, the controller 150 accesses the HDD serial-number storage unit 161 included in the flash memory 160 to check whether or not a HDD serial number is stored in the HDD serial-number storage unit 161 (step S10).

As a result of S10, if the controller 150 detects that the HDD serial number is stored in the HDD serial-number storage unit 161 (YES in S11), the controller 150 ends the operation.

On the other hand, as a result of S10, if the controller 150 detects that the HDD serial number is not stored in the HDD serial-number storage unit 161 (NO in S11), the controller 150 accesses the hard disk I/F 141 included in the HDD 140, and then temporarily memorizes a HDD serial number that is stored beforehand in the HDD serial-number storage area 142 of the hard disk I/F 141(S12). After that, the controller 150 stores the memorized HDD serial number in the HDD serial-number storage unit 161 included in the flash memory 160 (S13).

As a result, the HDD serial number of the HDD 140, which exists in the television apparatus 100 when the television apparatus 100 is used for the first time, is stored in the HDD serial-number storage unit 161 included in the flash memory 160. It is to be noted that a HDD serial number of the HDD 140 existing in the television apparatus 100 may also be written to the flash memory 160 beforehand, e.g. by the manufacturer at the time of factory shipment.

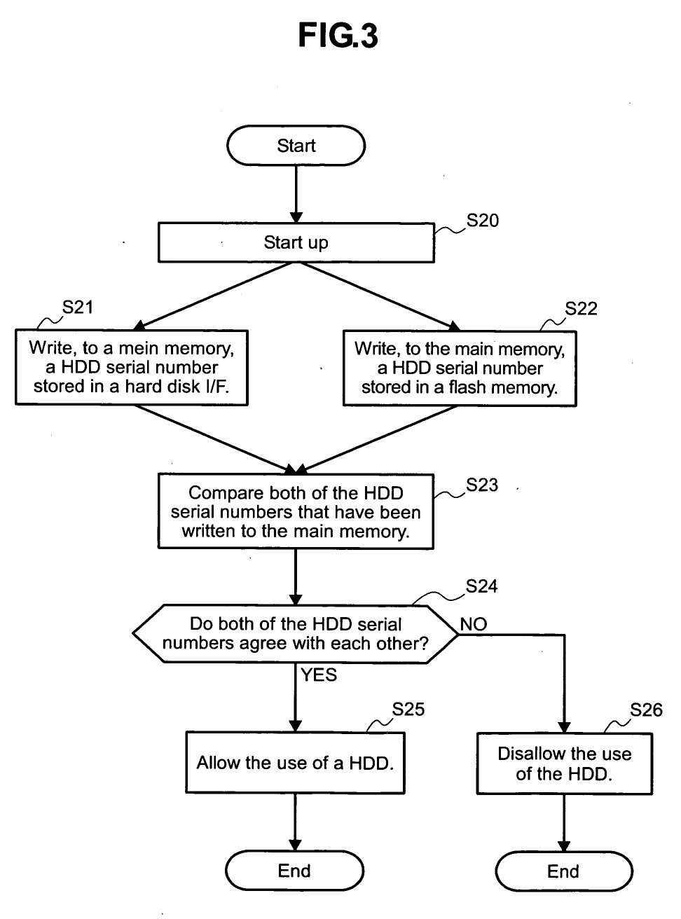

What will be described next with reference to FIG. 3 is a flow of operation performed when the power of the television apparatus 100 is turned on for the second time or later.

When the power of the television apparatus 100 is turned on, the controller 150 is started up (S20). As soon as the controller 150 is started up, the controller 150 loads, into the main memory 170, the HDD serial number that is stored in the HDD serial-number storage area 142 of the hard disk I/F 141(S21). In addition, the controller 150 loads, into the main memory 170, the HDD serial number that is stored in the flash memory 160 (S22). The controller 150 then compares the two HDD serial numbers in the main memory 170 (S23).

As a result of S23, if both of the HDD serial numbers agree with each other (YES in S24), the controller 150 allows the use of the HDD 140 (S25). For example, it becomes possible to write digital content to the HDD 140, or to read out digital content stored in the HDD 140.

On the other hand, as a result of S23, if both of the HDD serial numbers do not agree with each other (NO in S24), the controller 150 disallows the use of the HDD 140 (S26). For example, it is not possible to write digital content to the HDD 140, or it is not possible to read out digital content stored in the HDD 140.

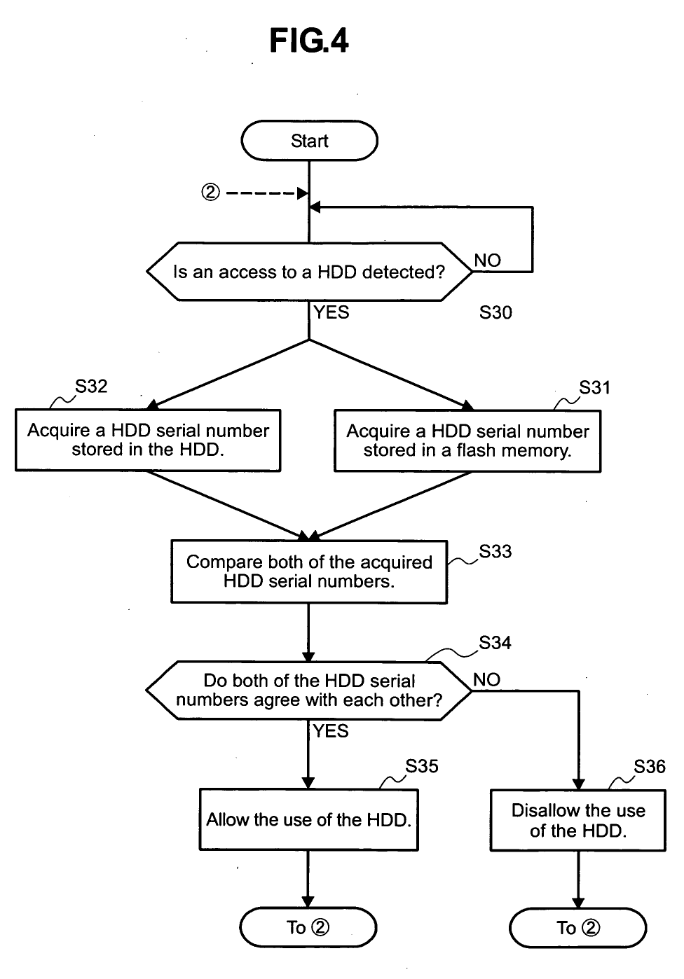

Incidentally, for example, the controller 150 is capable of receiving a picture-recording instruction from an unillustrated operation unit (for example, a remote controller) of the television apparatus 100, and controlling the stream control circuit 130 according to the picture recording instruction so that a received broadcast signal (digital content) is written to the HDD 140. Such processing enables accesses to the HDD 140 while the power of the television apparatus 100 stays in an ON state. A flow of operation performed while the power of the television apparatus 100 stays in the ON state will be described with reference to FIG. 4 as below.

As shown in FIG. 4, the controller 150 monitors whether or not an access to the HDD 140 is made. The controller 150 continues the monitoring until an access to the HDD 140 is detected (NO in S30). If the controller 150 detects an access to the HDD 140 (YES in S30), the controller 150 loads, into the main memory 170, the HDD serial number that is stored in the HDD serial-number storage area 142 of the hard disk I/F 141(S31). In addition, the controller 150 loads, into the main memory 170, the HDD serial number that is stored in the flash memory 160 (S32). The controller 150 then compares the two HDD serial numbers in the main memory 170 (S33). As a result, if both of the HDD serial numbers agree with each other (YES in S34), the controller 150 allows the use of the HDD 140 (S35). On the other hand, if both of the HDD serial numbers do not agree with each other (NO in S34), the controller 150 disallows the use of the HDD 140 (S36).

Thus, while the power of the television apparatus 100 stays in the ON state, the controller 150 acquires a HDD serial number from the HDD 140 every time an access to the HDD 140 is made, and then makes a judgment as to whether or not the acquired HDD serial number agrees with the HDD serial number that has been legally written to the flash memory 160 (for example, the number that has been written when the power of the television apparatus 100 is turned on for the first time). If the result of the judgment is negative, the controller 150 disallows the use of the HDD 140. Incidentally, as a case where an access to the HDD 140 is detected, there is, for example, a case where the controller 150 receives a picture-recording instruction through the above-mentioned operation unit, a case where the stream control circuit 130 is instructed to read out digital content from the HDD 140, or the like.

As described above, according to the above embodiment, if the HDD 140 is hot-swapped with a new one, it is possible to disallow the use of the HDD that is newly mounted by means of the hot swapping. This will be specifically described as below.

In this embodiment, as described with reference to FIG. 3, when the power of the television apparatus 100 is turned on, the controller 150 reads out, into the main memory 170, the HDD serial number in the HDD 140 and the HDD serial number in the flash memory 160. Then, the controller 150 compares the two HDD serial numbers that has been read out into the main memory 170. On the basis of the result of the comparison, the controller 150 allows or disallows the use of the HDD 140.

However, if such processing is performed only when the power of the television apparatus 100 is turned on, and if, after that, while the power stays in the ON state, a comparison is made between, for example, the two HDD serial numbers that have been stored in the main memory 170 by the processing in FIG. 3, when the HDD 140 is hot-swapped with a new one, it is not possible to disallow the use of the new HDD. To be more specific, when the HDD 140 is replaced with another HDD with the power of the television apparatus 100 being kept in the ON state, it is not possible to disallow the use of the another HDD. It is because one of the two HDD serial numbers stored in the main memory 170 has been read out from the HDD 140 before the hot swapping. Accordingly, for example, if a malicious user carries out hot swapping, the user is allowed to use a HDD that is newly mounted by means of the hot swapping, with the result that digital content is written to the new HDD. This means that digital content illegally flows into the new HDD.

For this reason, as described with reference to FIG. 4, while the power of the television apparatus 100 stays in the ON state, the controller 150 acquires a HDD serial number from the HDD 140 every time an access to the HDD 140 is made. The controller 150 then makes a judgment as to whether or not the acquired HDD serial number agrees with the HDD serial number that has been legally written to the flash memory 160. If the result of the judgment is negative, the controller 150 disallows the use of the HDD 140. Therefore, even if another HDD is mounted as a result of the hot swapping, a HDD serial number which is acquired from the another HDD at the time of an access to the another HDD does not agree with the HDD serial number that has been legally written to the flash memory 160. Accordingly, it is possible to disallow the use of the illegal HDD.

It is to be noted that the present technique is not limited to the above-mentioned embodiments, and that those skilled in the art will be able to make additions, deletions, and modifications within the scope of the preset technique. For example, because the flowcharts in the figures simply illustrate clear processing flows without losing understanding, and practices, of the present technique, those who skilled in the art can easily interchange, delete, and modify the steps. For example, in the embodiments described above, while the power of the television apparatus 100 stays in the ON state, every time an access to the HDD 140 is made, a comparison is made between the HDD serial number from the HDD 140 and the HDD serial number stored in the flash memory 160. However, the timing of the comparison is not limited to the time at which an access to the HDD 140 is made. For example, the comparison may also be periodically made, or the comparison may also be made in specified timing.

Although shown as a television receiver in the example, those skilled in the art will recognize that the techniques outlined above may be implemented on any receiver configured for receiving digital information, such as digital video signals and/or digital audio signals, and for storing and/or reproducing the digital information. Control operations described above may be carried out by execution of software, firmware, or microcode operating on a processor based digital television signal receiver, digital video recorder or on a computer of any type. Additionally, code for implementing such operations may be in the form of computer instruction in any form (e.g. source code, object code, interpreted code, etc.) stored in or carried by any computer or machine readable medium.

Program aspects of the technology may be thought of as “products,” typically in the form of executable code and/or associated data that is carried on or embodied in a type of machine readable medium. The executable code and/or associated data controls the operation of the broadcast receiver, recorder, computer or other programmable device for implementing the recording, and/or playback. Media include any or all of the memory of the broadcast receiver or associated modules thereof, such as various semiconductor memories, tape drives, disk drives and the like, which may provide storage at any time for the software programming. All or portions of the software may at times be communicated through the Internet or various other telecommunication networks. Such communications, for example, may enable loading of the software from another computer (not shown) into the reproducing apparatus or into another element, such as a web server used for software distribution or distribution of broadcast related information. Thus, another type of media that may bear the software elements includes optical, electrical and electromagnetic waves, such as used across physical interfaces between local devices, through wired and optical landline networks and over various air-links. The physical elements that carry such waves, such as wired or wireless links, optical links or the like, also may be considered as media bearing the software.

Terms regarding computer or machine “readable medium” (or media) as used herein therefore relate to any physical medium or transmission medium that participates in providing instructions or code or data to a processor for execution or processing. Such a medium may take many forms, including but not limited to, non-volatile media and volatile media as well as carrier wave and physical transmission media.

While the foregoing has described what are considered to be the best mode and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

What is claimed is:

1. A receiver comprising:
an input unit for receiving a signal containing broadcast data;
a storage unit having identification data which specifies the storage unit, for storing the received broadcast data;
a controller for controlling an access to the storage unit;
a memory storing a valid identification data; and
an output device for outputting the data stored in the storage unit;
wherein the controller:
(i) acquires the storage unit identification data from the storage unit and compares it with the valid identification data stored in the memory, and
(ii) allows the access to the storage unit only if the acquired storage unit identification data coincides with the valid identification data.

2. A receiver according to claim 1, further comprising:
a circuit for encrypting the received data for storage in the storage unit and for decrypting stored data retrieved from the storage unit.

3. A receiver according to claim 1, wherein the input unit includes a tuner which receives broadcast data.

4. A receiver according to claim 1, wherein the controller checks coincidence of the stored valid identification data and the acquired identification data of the storage unit periodically or every time an access to the storage unit is attempted.

5. A receiver according to claim 1, wherein the valid identification data is a serial number of the storage unit.

6. A receiver according to claim 1, wherein the storage unit comprises a hard disc drive, and the output device comprises a display.

7. A receiver according to claim 1, wherein the storage unit comprises:
a first area for storing the identification data of the storage unit; and
a second area different from the first area, for storing the received broadcasting data.

8. A receiver according to claim 1, wherein the valid identification data comprises an identification stored in the memory in advance by a manufacturer.

9. A receiver according to claim 1, wherein the valid identification data comprises an identification of a storage unit initially included in the receiver which was acquired and stored in the memory upon first power-up of the receiver.

10. A storage control method for controlling the use of a storage device having an identification data, said storage control method comprising:
acquiring the identification data from the storage device when the power is first turned on to the storage device;
storing the identification data;
acquiring identification data from a storage device during a subsequent operation; and
allowing accessing of the storage device only if the stored identification data and the indentification data acquired during subsequent operation match.

11. A storage control method according claim 10, wherein the acquiring of the identification data during subsequent operation is performed periodically or every time an access to the storage device is attempted.

12. A storage control method according claim 10, further comprising:
receiving broadcast data;
encrypting the received data when recording the received data to the storage unit; and
decrypting reproduced data when reproducing stored data accessed from the storage

13. A storage control method according claim 10, wherein the identification data is a serial number of the storage unit.

14. A product comprising instructions for causing a programmable device to perform the steps comprising:
acquiring the identification data from the storage device when the power is first turned on to the storage device;
storing the identification data;
acquiring identification data from a storage device during a subsequent operation; and
allowing accessing of the storage device only if the stored identification data and the identification data acquired during subsequent operation match.

15. A product according to claim 14, wherein the acquiring of the identification data during subsequent operation is performed periodically or every time an access to the storage device is attempted.

16. A product according to claim 14, wherein the steps further comprise:
receiving broadcast data;
encrypting the received data when recording the received data to the storage unit; and
decrypting reproduced data when reproducing stored data accessed from the storage unit.
